(19) United States
(12) Patent Application Publication
(10) Pub. No.: US 2016/0172421 A1
(43) Pub. Date: Jun. 16, 2016

(54) DISPLAY UNIT, METHOD OF MANUFACTURING THE SAME, AND ELECTRONIC APPARATUS

(71) Applicant: Sony Corporation, Tokyo (JP)

(72) Inventors: Makoto Ando, Tokyo (JP); Tomoo Fukuda, Tokyo (JP)

(73) Assignee: Sony Corporation, Tokyo (JP)

(21) Appl. No.: 14/745,916

(22) Filed: Jun. 22, 2015

(30) Foreign Application Priority Data
Dec. 12, 2014 (JP) 2014-251716

(51) Int. Cl. H01L 27/32; H01L 51/56

(52) U.S. Cl. CPC H01L 27/326; H01L 27/3209; H01L 27/3246; H01L 51/56; H01L 2227/323

(57) ABSTRACT

A display unit includes: a substrate; a plurality of pixels provided on the substrate, each of the pixels including a light-emitting device, the light-emitting devices being configured to emit colors different from one another; and a concave section provided between adjacent pixels of the pixels, the adjacent pixels including the light-emitting devices of colors at least different from each other.

### CROSS REFERENCE TO RELATED APPLICATIONS

This application claims the benefit of Japanese Priority Patent Application JP 2014-251716 filed Dec. 12, 2014, the entire contents of each which is incorporated herein by reference.

### BACKGROUND

The present technology relates to a display unit, a method of manufacturing the same, and an electronic apparatus including the display unit.

In recent years, a method of forming an organic layer of an organic EL (electroluminescence) device by a printing method has been proposed. The printing method holds promise because of lower process cost than that in a vacuum deposition method, easy upsizing, and the like.

The printing method is broadly divided into non-contact printing and contact printing. Examples of the non-contacting printing may include an ink-jet method and a nozzle printing method. Examples of the contact printing may include a flexographic printing method, a gravure offset printing method, and a reverse offset printing method.

In the reverse offset printing method, after a film of an ink is uniformly formed on a surface of a blanket, the blanket is pressed against a plate to remove a non-printing portion, and then a pattern remaining on the blanket is transferred to a printing target. The surface of the blanket may be formed of, for example, silicon rubber. The reverse offset printing method is considered as a promising method for application to an organic EL device, since a film with a uniform thickness is formable, and high-definition patterning is allowed to be performed (for example, refer to Japanese Unexamined Patent Application Publication No. 2010-158799).

### SUMMARY

However, for example, in a case where a light-emitting layer of an organic EL device is formed with use of the reverse offset printing method, it is necessary to maintain a predetermined distance between pixels in consideration of variation in printing position and pattern size, and it is difficult to achieve a high-definition display unit.

It is desirable to provide a display unit with high definition and high reliability, a method of manufacturing the same, and an electronic apparatus.

According to an embodiment of the present technology, there is provided a display unit including: a substrate; a plurality of pixels provided on the substrate, each of the pixels including a light-emitting device, the light-emitting devices being configured to emit colors different from one another; and a concave section provided between adjacent pixels of the pixels, the adjacent pixels including the light-emitting devices of colors at least different from each other.

According to an embodiment of the present technology, there is provided a method of manufacturing a display unit including: forming a concave section between pixels provided on a substrate, each of the pixels including a light-emitting device, the light-emitting devices configured to emit colors different from each other; and forming the light-emitting devices in the pixels.

According to an embodiment of the present technology, there is provided an electronic apparatus provided with a display unit, the display unit including: a substrate; a plurality of pixels provided on the substrate, each of the pixels including a light-emitting device, the light-emitting devices being configured to emit colors different from one another; and a concave section provided between adjacent pixels of the pixels, the adjacent pixels including the light-emitting devices of colors at least different from each other.

In the display unit, the method of manufacturing the display unit, and the electronic apparatus according to the embodiments of the present technology, the concave section is provided between the pixels including the light-emitting devices configured to emit colors different from each other; therefore, for example, a narrow space between the pixels in consideration of a printing position and variation in pattern size is allowed to be designed.

In the display unit, the method of manufacturing the display unit, and the electronic apparatus according to the embodiments of the present technology, the concave section is provided between the pixels including the light-emitting devices configured to emit colors different from each other. Therefore, a distance (pitch) between the pixels in consideration of the printing position and variation in pattern size is allowed to be decreased. In other words, image resolution is allowed to be improved, and a display unit with high definition and high reliability and an electronic apparatus including the display unit are allowed to be provided. It is to be noted that effects of the embodiments of the present technology are not limited to effects described here, and may include any effect described in this description.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the technology, and are incorporated in and constitute a part of this specification. The drawings illustrate embodiments and, together with the specification, serve to explain the principles of the technology.

FIG. 1 is a sectional view and a plan view of a display unit according to an embodiment of the present technology.

FIG. 2 is a sectional view of the display unit illustrated in FIG. 1.

FIG. 3 is a diagram illustrating an example of a pixel drive circuit illustrated in FIG. 2.

FIG. 4A is a sectional view illustrating a process of a method of manufacturing the display unit illustrated in FIG. 1.

FIG. 4B is a sectional view illustrating a process following FIG. 4A.

FIG. 4C is a sectional view illustrating a process following FIG. 4B.

FIG. 4D is a sectional view illustrating a process following FIG. 4C.

FIG. 5A is a sectional view illustrating a process following FIG. 4D.

FIG. 5B is a sectional view illustrating a process following FIG. 5A.

FIG. 5C is a sectional view illustrating a process following FIG. 5B.

FIG. 6A is a sectional view illustrating a process following FIG. 5C.

FIG. 6B is a sectional view illustrating a process following FIG. 6A.

FIG. 6C is a sectional view illustrating a process following FIG. 6B.

FIG. 7A is a sectional view illustrating a process following FIG. 6C.

FIG. 7B is a sectional view illustrating a process following FIG. 7A.

FIG. 7C is a sectional view illustrating a process following FIG. 7B.

FIG. 7D is a sectional view illustrating a process following FIG. 7C.

FIG. 8A is a sectional view illustrating a process of a method of forming a light-emitting layer according to a comparative example.

FIG. 8B is a sectional view illustrating a process following FIG. 8A.

FIG. 8C is a sectional view illustrating a process following FIG. 8B.

FIG. 8D is a sectional view illustrating a process following FIG. 8C.

FIG. 9A is a sectional view illustrating a process following FIG. 8D.

FIG. 9B is a sectional view illustrating a process following FIG. 9A.

FIG. 9C is a sectional view illustrating a process following FIG. 9B.

FIG. 9D is a sectional view illustrating a process following FIG. 9C.

FIG. 10 is a sectional view of a display unit according to a modification example of the present technology.

FIG. 11 is a plan view illustrating a schematic configuration of a module including the above-described display unit.

FIG. 12A is a perspective view illustrating an appearance viewed from a front side of Application Example 1 of the above-described display unit.

FIG. 12B is a perspective view illustrating an appearance viewed from a back side of Application Example 1 illustrated in FIG. 12A.

FIG. 13A is a perspective view illustrating an example of an appearance of Application Example 2 of the above-described display unit.

FIG. 13B is a perspective view illustrating another example of the appearance of Application Example 2 of the above-described display unit.

FIG. 14 is a perspective view illustrating an example of an appearance using the above-described display unit as an illumination unit.

FIG. 15 is a perspective view illustrating another example of the appearance using the above-described display unit as an illumination unit.

FIG. 16 is a perspective view illustrating another example of the appearance using the above-described display unit as an illumination unit.

### DETAILED DESCRIPTION

Some embodiments of the present technology will be described in detail below referring to the accompanying drawings. It is to be noted that description will be given in the following order.

1. Embodiment (An example in which a concave section is provided between pixels by forming a recessed-protruding portion in a planarization layer)

1-1. Main Part Configuration

1-2. Entire Configuration

1-3. Manufacturing Method

1-4. Functions and Effects

2. Modification Example (An example in which a concave section is provided between pixels by a thickness of a pixel electrode)

3. Application Examples

### Embodiment

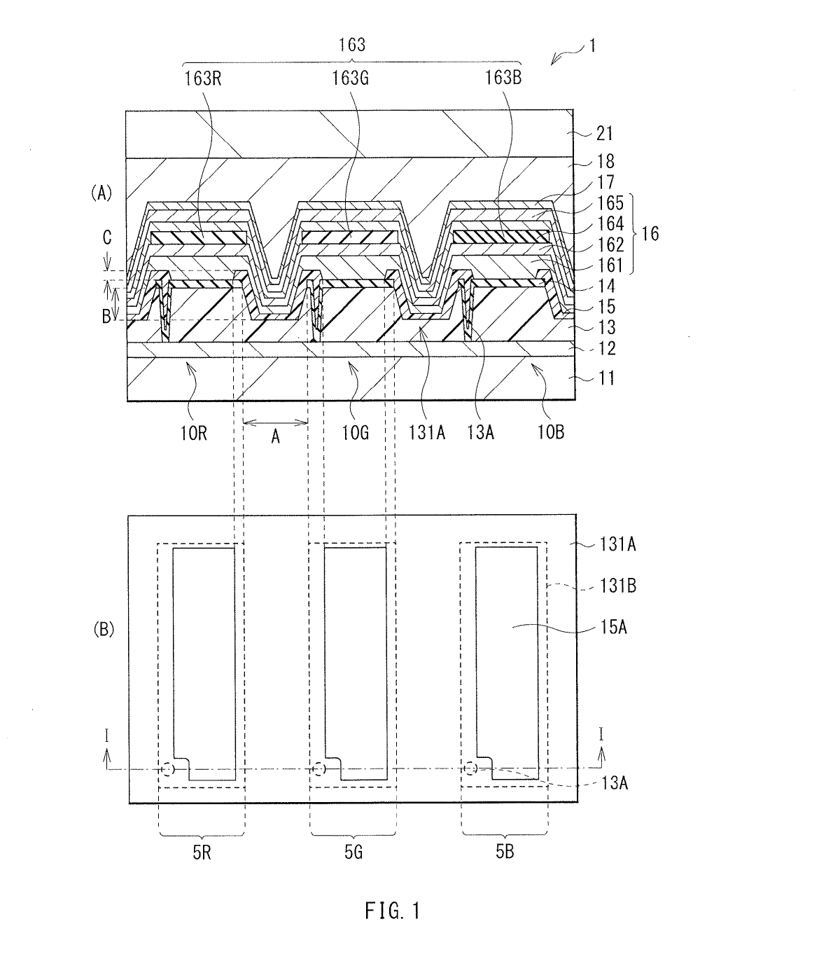

A part (A) in FIG. 1 illustrates a sectional configuration of a display unit (a display unit 1) according to an embodiment of the present technology, and a part (B) in FIG. 1 schematically illustrates a planar configuration of a pixel aperture (an aperture 15A) and the like of the display unit 1 illustrated in FIG. 1. It is to be noted that the part (A) in FIG. 1 is a sectional view taken along a line I-I illustrated in the part (B) in FIG. 1. The display unit 1 may be used as, for example, a mobile terminal unit such as a tablet or a smartphone. The display unit 1 may be an organic EL display unit, and may have, for example, a configuration in which red organic EL devices 10R, green organic EL devices 10G, and blue organic EL devices 10B are formed as light-emitting devices on a drive substrate 11 with a TFT (Thin Film Transistor) layer 12 and a planarization layer 13 in between.

### (1-1. Main Part Configuration)

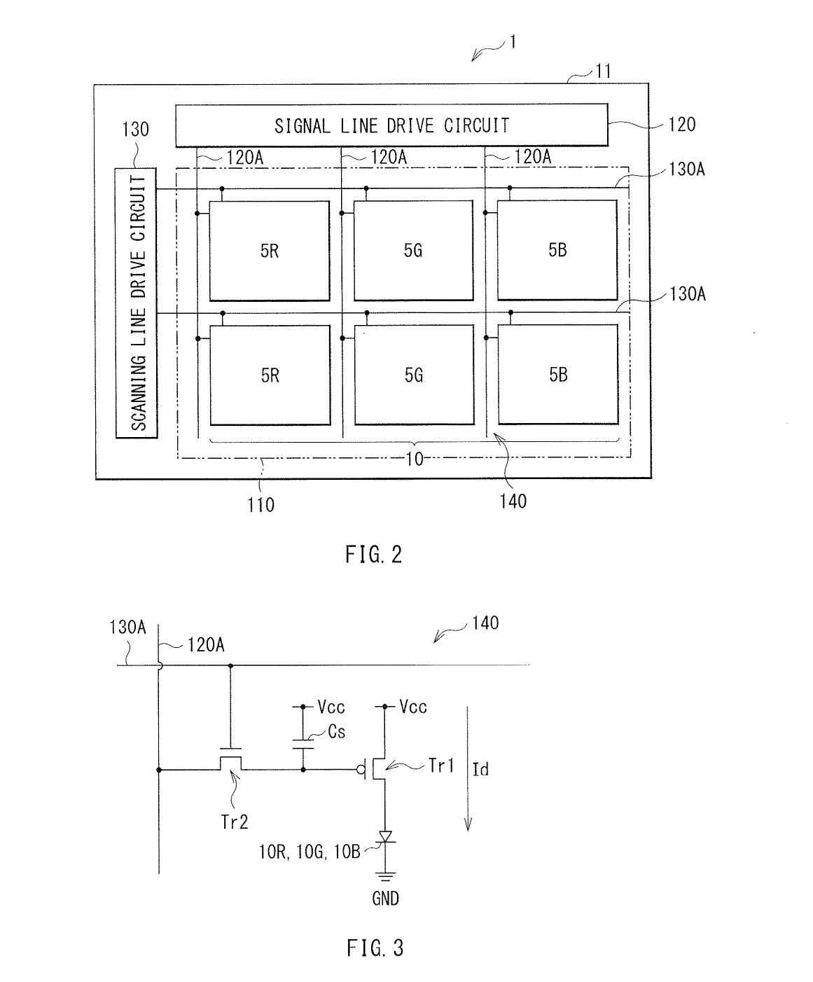

In the display unit 1 according to this embodiment, as illustrated in FIG. 2, a plurality of sub-pixels (red sub-pixels 5R, green sub-pixels 5G, and blue sub-pixels 5B) are arranged in a matrix in a display region 110 of the drive substrate 11, and concave sections (concave sections 131A) illustrated in the parts (A) and (B) in FIG. 1 are provided between sub-pixels of different colors of the plurality of sub-pixels.

As illustrated in the parts (A) and (B) in FIG. 1, the concave sections 131A are provided between sub-pixels of different colors (the red sub-pixel 5R, the green sub-pixel 5G, and the blue sub-pixel 5B). As will be described in detail later, the concave sections 131A are provided so that when light-emitting layer 163R, 163G, or 163B is formed with use of, for example, a printing method in a process of manufacturing the organic EL devices (the red organic EL devices 10R, the green organic EL devices 10G, and the blue organic EL devices 10B), a resist is prevented from remaining in portions that overlap light-emitting layers of colors different from the color of the light-emitting layers 163R, 163G, or 163B.

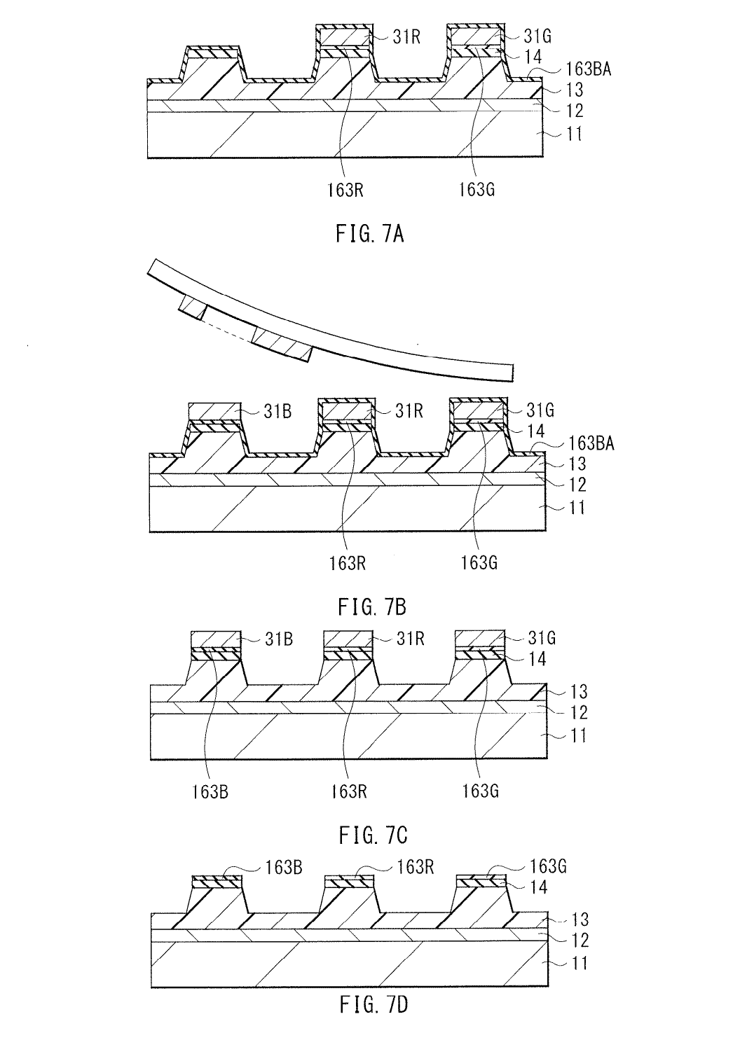

In this embodiment, the concave sections 131A are formed in the planarization layer 13. A distance to a bottom surface of the concave section 131A, specifically, a distance from a surface of a convex section of the planarization layer 13 to the bottom surface of the concave section 131A provided between the sub-pixels, i.e. a depth (B) may be preferably larger than a thickness (C) of a pixel separation film (a partition wall 15) on a pixel electrode 14 of the partition wall 15 covering from an outer edge portion of the pixel electrode 14 to a side surface and the bottom surface of the concave section 131B. More specifically, depending on the configuration of the display unit 1, the depth (B) may be preferably, for example, from about 0.5 μm to about 2 μm both inclusive. A ratio (A:B) between a distance (A) between pixels and the depth (B) of the concave section 131A may be preferably, for example, from about 1:1 to about 100:1 both inclusive in terms of easy processing and a depth for prevention of transfer of a mask (masks 31R, 31G, and 31B; for example, refer to FIG. 7C) that will be described later. In this embodiment, the concave sections 131A are formed in the planarization layer 13 provided on a TFT layer 12 that will be described later. It is to be noted that each of the concave sections 131A may preferably have a tapered side surface. A possibility that a counter electrode 17 is brought out of conduction by a level difference is reduced by the tapered side surface of the concave section 131A.

### (1-2. Entire Configuration)

FIG. 2 illustrates an entire configuration of the display unit 1. The display unit 1 is configured of a plurality of sub-pixels (the red sub-pixels 5R, the green sub-pixels 5G, and the blue sub-pixels 5B) arranged in a matrix as a display region 110 on the drive substrate 11. A signal line drive circuit 120 and a scanning line drive circuit 130 as image display drivers are provided around the display region 110. It is to be noted that, in each of the sub-pixels 5R, 5G, and 5B, an organic EL device 10 corresponding thereto (the red organic EL device 10R, the green organic EL device 10G, or the blue organic EL device 10B) is provided, and a combination of one sub-pixel 5R, one sub-pixel 5G, and one sub-pixel 5B that are adjacent to one another configures one pixel.

In the display region 110, in addition to the red organic EL devices 10R, the green organic EL devices 10G, and the blue organic EL devices 10B, a pixel drive circuit 140 configured to drive the organic EL device 10R, 10G, or 10B is provided. FIG. 3 illustrates an example of the pixel drive circuit 140. The pixel drive circuit 140 may be an active drive circuit formed in a layer (for example, a TFT layer 12) below the pixel electrode 14 that will be described later. In other words, the pixel drive circuit 140 includes a driving transistor Tr1, a writing transistor Tr2, a capacitor (a retention capacitor) Cs disposed between the transistors Tr1 and Tr2, and the red organic EL device 10R (or the green organic EL device 10G or the blue organic EL device 10B) connected in series to the driving transistor Tr1 between a first power supply line (Vcc) and a second power supply line (GND). Each of the driving transistor Tr1 and the writing transistor Tr2 may be configured of a typical thin film transistor (TFT), and may have, for example, but not exclusively, an inverted stagger configuration (a so-called bottom gate configuration) or a stagger configuration (a top gate configuration).

In the pixel drive circuit 140, a plurality of signal lines 120A are arranged along a column direction, and a plurality of scanning lines 130A are arranged along a row direction. An intersection of each signal line 120A and each scanning line 130A corresponds to one of the red organic EL device 10R, the green organic EL device 10G, and the blue organic EL 10B. Each of the signal lines 120A is connected to the signal line drive circuit 120, and an image signal is supplied from the signal line drive circuit 120 to a source electrode of the writing transistor Tr2 through the signal line 120A. Each of the scanning lines 130A is connected to the scanning line drive circuit 130, and a scanning signal is sequentially supplied from the scanning line drive circuit 130 to a gate electrode of the writing transistor Tr2 through the scanning line 130A.

The signal line drive circuit 120 is configured to supply a signal voltage of an image signal according to luminance information supplied from a signal supply source (not illustrated) to the selected red organic EL device 10R, the selected green organic EL device 10G, or the selected blue organic EL device 10B through the signal line 120A. The scanning line drive circuit 130 is configured of a shift register or the like configured to shift (transfer) a start pulse in synchronization with an inputted clock pulse. The scanning line drive circuit 130 is configured to scan the pixels 10 row by row upon writing of an image signal to each of the pixels 10 and sequentially supply a scanning signal to each of the scanning lines 130A. The signal voltage from the signal line drive circuit 120 and the scanning signal from the scanning line drive circuit 130 are supplied to the signal line 120A and the scanning line 130A, respectively.

Next, referring again to FIG. 1, a specific configuration of the drive substrate 11, the TFT layer 12, the planarization layer 13, the organic EL devices 10 (the red organic EL devices 10R, the green organic EL devices 10G, and the blue organic EL devices 10B), and the like will be described below.

The drive substrate 11 is a supporting body with a flat surface on which the red organic EL devices 10R, the green organic EL devices 10G, and the blue organic EL devices 10G are formed in an array. Examples of the material of the drive substrate 11 may include known materials such as quartz, glass, metal foil, and a film or a sheet made of a resin. In particular, quartz or glass may be preferably used. In a case where the film or the sheet made of the resin is used, as the resin, methacrylate resins typified by poly(methyl methacrylate) (PMMA), polyesters such as polyethylene terephthalate (PET), polyethylene naphthalate (PEN), and polybutylene naphthalate (PBN), and a polycarbonate resin, and the like may be used; however, in this case, to suppress water permeability and gas permeability, the drive substrate 11 may preferably have a laminate configuration, and may be preferably subjected to surface treatment.

As described above, in the TFT layer 12, the pixel drive circuit 140 is formed, and the driving transistor Tr1 is electrically connected to the pixel electrode 14. The planarization layer 13 is configured to planarize a surface of the driving substrate 11 (the TFT layer 12) in which the pixel drive circuit 140 is formed, and may be preferably made of a material with high pattern accuracy, since a fine connection hole (not illustrated) allowing the driving transistor Tr1 and the pixel electrode 14 to be connected to each other is formed in the planarization layer 13. Examples of the material of the planarization layer 13 may include an organic material such as polyimide and an inorganic material such as silicon oxide (SiO₂). In this embodiment, the concave sections 131A are formed in the planarization layer 13.

Each of the red organic EL devices 10R, the green organic EL devices 10G, and the blue organic EL devices 10B includes the pixel electrode 14 as an anode, an organic layer 16, and the counter electrode 17 as a cathode in this order from the drive substrate 11. The organic layer 16 includes a hole injection layer 161, a hole transport layer 162, a light-emitting layer 163, an electron transport layer 164, and an electron injection layer 165 in this order from the pixel electrode 14. The light-emitting layer 163 is configured of a red light-emitting layer 163R, a green light-emitting layer 163G, and a blue light-emitting layer 163B, and the red light-emitting layer 163R, the green light-emitting layer 163G, and the blue light-emitting layer 163B are provided for the red organic EL device 10R, the green organic EL device 10G, and the blue organic EL device 10B, respectively.

The pixel electrode 14 is provided on the planarization layer 13 for each of the red organic EL devices 10R, the green organic EL devices 10G, and the blue organic EL devices 10B, and may be made of, for example, a transparent material of a simple substance or an alloy of a metal element such as chromium (Cr), gold (Au), platinum (Pt), nickel (Ni), copper (Cu), tungsten (W), or silver (Ag). Alternatively, the pixel electrode 14 may be configured of a laminate configuration of the above-described metal film and a transparent conductive film. Examples of the transparent conductive film may include an oxide of indium and tin (ITO), indium-zinc oxide (InZnO), and an alloy of zinc oxide (ZnO) and aluminum (Al). In a case where the pixel electrode 14 is used as an anode, the pixel electrode 14 may be preferably made of a material with high hole injection properties; however, even if a material with an insufficient work function such as an aluminum alloy is used for the pixel electrode 14, the pixel electrode 14 may function as an anode by providing the appropriate hole injection layer 161.

The partition wall 15 is configured to secure insulation between the pixel electrode 14 and the counter electrode 17 and to form a light emission region into a desired shape, and has an aperture corresponding to the light emission region. Layers above the partition wall 15, i.e., layers from the hole injection layer 161 to the counter electrode 17 may be provided not only on the aperture but also on the partition wall 15; however, light is emitted only from the aperture. The partition wall 15 may be made of, for example, an inorganic insulating material such as silicon oxide or an organic insulating material such as photosensitive polyimide. In this embodiment, the partition wall 15 is so formed with a uniform thickness from the side surface to the bottom surface of each of the concave sections 131A provided between the pixels as to keep the shape of each of the concave sections 131A. The thickness (C) of the partition wall 15 may be preferably smaller than the depth (B) of the concave section 131A, and may be preferably, for example, from about 0.1 μm to about 1 μm both inclusive, depending on the entire configuration of the organic EL device 10. It is to be noted that as long as the concave sections 131A between the sub-pixels are allowed to be maintained, the thickness of the partition wall 15 is not necessarily uniform on the pixel electrode 14 and the side surface and the bottom surface of each of the concave sections 131A.

The hole injection layer 161 is shared by the red organic EL devices 10R, the green organic EL devices 10G, and the blue organic EL devices 10B, and is configured to enhance hole injection efficiency and function as a buffer layer configured to prevent leakage. The hole injection layer 161 may be formed preferably with, for example, a thickness of about 5 nm to about 100 nm both inclusive, and more preferably with a thickness of about 8 nm to about 50 nm both inclusive.

Examples of the material of the hole injection layer 161 may include polyaniline and a derivative thereof, polythiophene and a derivative thereof, polypyrrole and a derivative thereof, polyphenylene and a derivative thereof, polythienylene vinylene and a derivative thereof, polyquinoline and a derivative thereof, polyquinoxaline and a derivative thereof, a conductive polymer such as a polymer including an aromatic amine structure in a main chain or a side chain, metal phthalocyanine (such as copper phthalocyanine), and carbon. The material of the hole injection layer 161 may be appropriately selected, depending on a relationship with the material of an electrode or a layer adjacent thereto.

In a case where the hole injection layer 161 is made of a polymer material, the weight-average molecular weight (Mw) of the polymer material may be, for example, from about 2000 to about 300000 both inclusive, and may be preferably from about 5000 to about 200000 both inclusive. When the Mw is less than about 5000, there is a possibility that the polymer material is dissolved when the hole transport layer 162 and layers thereabove are formed, and when the Mw exceeds about 300000, film formation may be difficult due to gelation of the material.

Examples of a typical polymer material used for the hole injection layer 161 may include polyaniline and/or oligoaniline, and polydioxythiophene such as poly(3,4-ethylenedioxythiophene) (PEDOT). As specific examples of the typical polymer material, Nafion (trademark) and Liquion (trademark) manufactured by H.C. Starck GmbH, ELsource (trademark) manufactured by Nissan Chemical Industries. Ltd., a conductive polymer called Verazol manufactured by Soken Chemical & Engineering Co., Ltd. or the like may be used.

In a case where the pixel electrode 14 is used as an anode, the pixel electrode 14 may be preferably formed of a material with high hole injection properties. However, for example, even a material with a relatively small work function value such as an aluminum alloy may be used as the material of the anode by providing the appropriate hole injection layer 161.

The hole transport layer 162 is configured to enhance hole transport efficiency to the light-emitting layer 163, and is so provided on the hole injection layer 161 as to be shared by the red organic EL devices 10R, the green organic EL devices 10G, and the blue organic EL devices 10B.

Depending on an entire device configuration, a thickness of the hole transport layer 162 may be, preferably from about 10 nm to about 200 nm both inclusive, and more preferably from about 15 nm to about 150 nm both inclusive. As a polymer material forming the hole transport layer 162, a light-emitting material soluble in an organic solvent, for example, polyvinylcarbazole and a derivative thereof, polyfluorene and a derivative thereof, polyaniline and a derivative thereof, polysilane and a derivative thereof, a polysiloxane derivative having an aromatic amine in a side chain or a main chain, polythiophene and a derivative thereof, polypyrrole, and the like may be used.

A weight-average molecular weight (Mw) of the polymer material may be preferably from about 50000 to about 300000 both inclusive, and may be specifically preferably from about 100000 to about 200000 both inclusive. In a case where the Mw is less than about 50000, upon formation of the light-emitting layer, a low-molecular-weight component in the polymer material is lost to cause a dot in a hole injection/transport layer; therefore, initial performance of the organic EL device may be degraded, or deterioration in the device may be caused. On the other hand, in a case where the Mw exceeds 300000, film formation may be difficult due to gelation of the material.

It is to be noted that the weight-average molecular weight (Mw) is a value determined by gel permiation chromatography (GPC) using polystyrene standards with use of tetrahydrofuran as a solvent.

The light-emitting layer 163 is configured to emit light by the recombination of electrons and holes in response to the application of an electric field. The red light-emitting layer 163R may be made of, for example, a light-emitting material having one or more peaks in a wavelength range of about 620 nm to about 750 nm both inclusive, the green light-emitting layer 163G may be made of, for example, a light-emitting material having one or more peaks in a wavelength range of about 495 nm to about 570 nm both inclusive, and the blue light-emitting layer 163B may be made of, for example, a light-emitting material having one or more peaks in a wavelength range of about 450 nm to about 495 nm both inclusive. Depending on the entire device configuration, a thickness of the light-emitting layer 163 may be preferably, for example, from about 10 nm to about 200 nm both inclusive, and more preferably from about 15 nm to about 100 nm both inclusive.

For the light-emitting layer 163, for example, a mixed material prepared by adding a low-molecular-weight material (a monomer or an oligomer) to a polymer (light-emitting) material may be used. Examples of the polymer material forming the light-emitting layer 163 may include a polyfluorene-based polymer derivative, a (poly)paraphenylene vinylene derivative, a polyphenylene derivative, a polyvinylcarbazole derivative, a polythiophene derivative, a perylene-based pigment, a coumarin-based pigment, a rhodamine-based pigment, and the above-described polymer material doped with an organic EL material. As a doping material, for example, rubrene, perylene, 9,10-diphenylanthracene, tetraphenyl butadiene, nile red, or Coumarin6 may be used.

The electron transport layer 164 is configured to enhance electron transport efficiency to the light-emitting layer 163, and is provided as a common layer shared by the red organic EL devices 10R, the green organic EL devices 10G, and the blue organic EL devices 10B. Examples of the material of the electron transport layer 164 may include quinoline, perylene, phenanthroline, phenanthrene, pyrene, bisstyryl, pyrazine, triazole, oxazole, fullerene, oxadiazole, fluorenone, anthracene, naphthalene, butadiene, coumarin, acridine, stilbene, derivatives thereof, and metal complexes thereof. As an example of the metal complex, tris(8-hydroxyquinoline) aluminum (Alq3 for short) may be used as the material of the electron transport layer 164.

The electron injection layer 165 is configured to enhance electron injection efficiency, and is provided as a common layer on an entire surface of the electron transport layer 164. As the material of the electron injection layer 165, for example, lithium oxide (Li₂O) which is an oxide of lithium (Li), cesium carbonate (Cs₂CO₃) which is a complex oxide of cesium, or a mixture of the oxide and the complex oxide thereof may be used. Moreover, as the material of the electron injection layer 165, a simple substance or an alloy of an alkali-earth metal such as calcium (Ca) or barium (Ba), an alkali metal such as lithium or cesium, or a metal with a small work function such as indium (In) or magnesium (Mg) may be used. Alternatively, oxides, complex oxides, and fluorides of the metals, and a mixture thereof may be used.

The counter electrode 17 is provided on an entire surface of the electron injection layer 165 while being insulated from the pixel electrode 14. In other words, the counter electrode 17 is a common electrode shared by the red organic EL devices 10R, the green organic EL devices 10G, and the blue organic EL devices 10B. The counter electrode 17 may be made of, for example, aluminum (Al) with a thickness of about 200 nm.

The red organic EL devices 10R, the green organic EL devices 10G, and the blue organic EL devices 10B may be covered with, for example, a protective layer (not illustrated), and a counter substrate 21 made of glass or the like is further bonded onto an entire surface of the protective layer with an sealing layer 18 made of a thermosetting resin, an ultraviolet curable resin, or the like in between.

The protective layer may be made of one of an insulating material and a conductive material, and may be formed with, for example, a thickness of about 2 μm to about 3 μm both inclusive. For example, an inorganic amorphous insulating material such as amorphous silicon (α-silicon), amorphous silicon carbide (α-SiC), amorphous silicon nitride (α-Si₁₋ₓNₓ) or amorphous carbon (α-C) may be used. Such an inorganic amorphous insulating material does not form grains; therefore, the inorganic amorphous insulating material has low water permeability, and forms a favorable protective film.

The counter substrate 21 is disposed close to the counter electrode 17 of the red organic EL devices 10R, the green organic EL devices 10G, and the blue organic EL devices 10B, and is configured to seal, together with an adhesive layer, the red organic EL devices 10R, the green organic EL devices 10G, and the blue organic EL devices 10B.

In the display unit 1, light from the red organic EL devices 10R, the green organic EL devices 10G, and the blue organic EL device 10B may be extracted from either the driving substrate 11 or the counter substrate 21, and the display unit 1 may be a bottom emission display unit or a top emission display unit. In a case where the display unit 1 is a bottom emission display unit, a color filter (not illustrated) may be provided between the red organic EL devices 10R, the green organic EL devices 10G, and the blue organic EL devices 10B, and the driving substrate 11. In a case where the display unit 1 is a top emission display unit, the color filter may be provided between the red organic EL devices 10R, the green organic EL devices 10G, and the blue organic EL devices 10B, and the counter substrate 21.

The color filter includes a red filter, a green filter, and a blue filter facing each of the red organic EL devices 10R, each of the green organic EL devices 10G, and each of the blue organic EL devices 10B, respectively. Each of the red filter, the green filter, and the blue filter is made of a resin including a pigment, and is allowed to be adjusted by appropriately selecting the pigment so as to have high light transmittance in a wavelength range of target red, green, or blue and low light transmittance in other wavelength ranges.

In the color filter, a light-shielding film is provided as a black matrix together with the red filter, the green filter, and the blue filter. By the color filter, light generated in the red organic EL devices 10R, the green organic EL devices 10G, and the blue organic EL devices 10B is extracted, and outside light reflected by the red organic EL devices 10R, the green organic EL devices 10G, the blue organic EL devices 10B, and wiring lines therebetween is absorbed, thereby obtaining high contrast. The light-shielding film may be configured of, for example, a black resin film that contains a black colorant and has optical density of about 1 or more, or a thin film filter using interference of a thin film. In particular, the light-shielding film may be preferably configured of the black resin film, since the light-shielding film is allowed to be formed easily at low cost. The thin film filter may be configured, for example, by laminating one or more thin films made of a metal, a metal nitride, or a metal oxide, and is configured to attenuate light with use of interference of the thin film. Specifically, a thin film filter configured by alternately laminating chromium (Cr) and chromium oxide (Cr₂O₃) may be used.

### (1-3. Manufacturing Method)

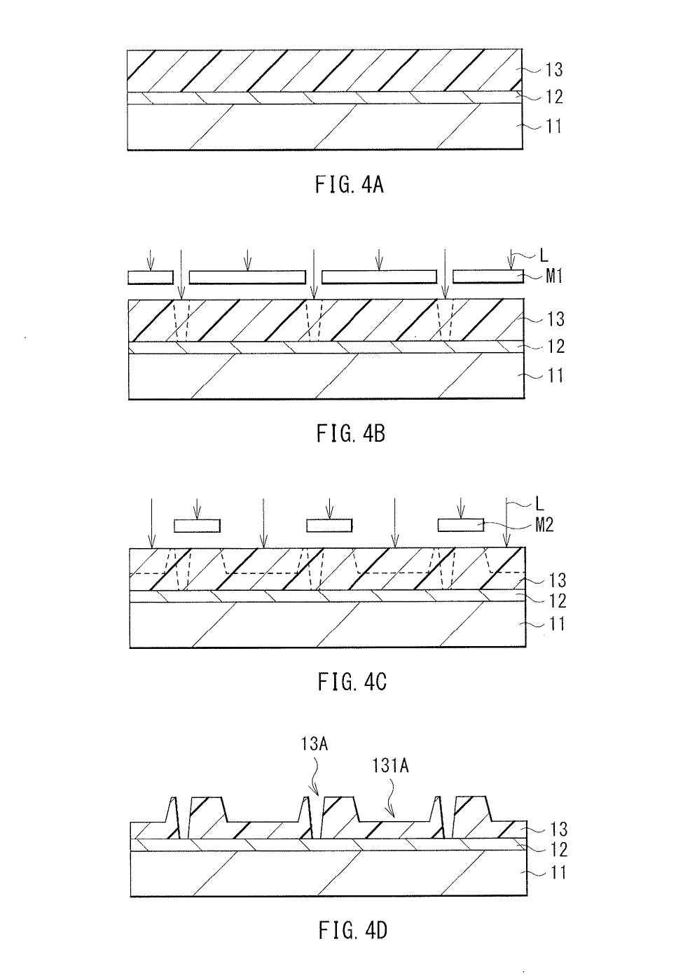

FIGS. 4A to 7C schematically illustrate processes of manufacturing the display unit 1 according to this embodiment. First, as illustrated in FIG. 4A, the TFT layer 12 is formed on the drive substrate 11 made of the above-described material, and then the planarization layer 13 is formed with use of, for example, a photosensitive polyimide. Subsequently, as illustrated in FIG. 4B, exposure of light (light L) is performed with use of a mask M1 having an opening at a position corresponding to the connection hole 13A between the pixel electrode 14 and a drain electrode of the driving transistor Tr1 (the TFT layer 12), and then, as illustrated in FIG. 4C, half exposure of light (the light L) is performed with use of a mask M2 having an opening at a position corresponding to a position between adjacent sub-pixels of different colors. Thereafter, as illustrated in FIG. 4D, the connection hole 13A and the concave section 131A are formed in the planarization layer 13 by performing development.

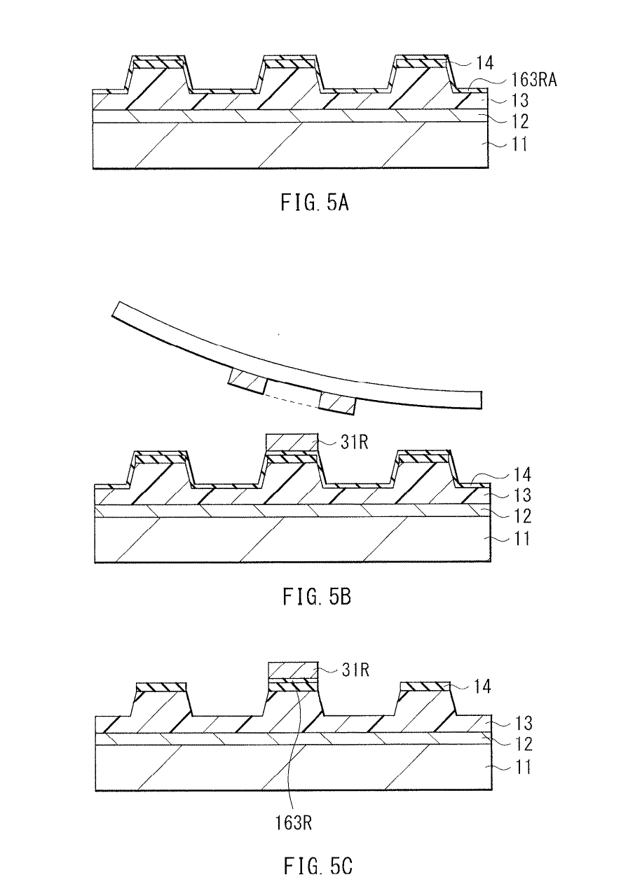

Subsequently, as illustrated in FIG. 5A, a transparent conductive film made of, for example, ITO is formed on the entire surface of the drive substrate 11, and patterning is performed on the conductive film, thereby forming the pixel electrode 14. At this time, the pixel electrode 14 is brought into conduction with the drain electrode of the driving transistor Tr1 (the TFT layer 12) through the connection hole 13 (not illustrated). Subsequently, although not illustrated in the drawings, a film of an inorganic insulating material such as SiO₂ is formed on the planarization layer 13 and the pixel electrode 14 by, for example, a CVD (Chemical Vapor Deposition) method, and then, a photosensitive resin is laminated on the film, and patterning is performed to form the partition wall 15. Alternatively, patterning may be performed with use of an organic insulating material such as a photosensitive polyimide to form the partition wall 15.

Subsequently, a front surface, i.e., a surface where the pixel electrode 14 and the partition wall 15 of the drive substrate 11 are formed is subjected to oxygen plasma treatment to remove contaminants such as an organic matter adhered to the surface, thereby improving wettability. More specifically, the drive substrate 11 is heated at a predetermined temperature, for example, from about 70° C. to about 80° both inclusive, and then is subjected to plasma treatment using oxygen as reactant gas (O₂ plasma treatment) under atmospheric pressure.

Subsequently, although not illustrated in the drawings, the hole injection layer 161 and the hole transport layer 162 are so formed as to be shared by the red organic EL devices 10R, the green organic EL devices 10G, and the blue organic EL devices 10B. A film of the above-described material of the hole injection layer 161 is formed on the pixel electrode 14 and the partition wall 15 by, for example, a spin coating method, and then is baked for one hour in the air, thereby forming the hole injection layer 161. After the hole injection layer 161 is formed, a film is formed by a spin coating method in a similar manner, and then is baked for one hour at about 180° C. under a nitrogen (N₂) atmosphere, thereby forming the hole transport layer 162.

Subsequently, as illustrated in FIGS. 5A to 7D, the red light-emitting layer 163R, the green light-emitting layer 163G, and the blue light-emitting layer 163B are formed for the red organic EL device 10R, the green organic EL device 10G, and the blue organic EL device 10B, respectively. In this embodiment, the light-emitting layer 163 (the red light-emitting layer 163R, the green light-emitting layer 163G, and the blue light-emitting layer 163B) is formed with use of masks (masks 31R, 31G, and 31B that will be described later). As will be described in detail later, deterioration of the red organic EL device 10R, the green organic EL device 10G, and the blue organic EL device 10B during manufacturing processes is allowed to be thereby suppressed. It is to be noted that, as described above, the partition wall 15, the hole injection layer 161, and the hole transport layer 162 are not illustrated in the drawings.

The light-emitting layer 163 is formed, for example, in order of the red light-emitting layer 163R, the green light-emitting layer 163G, and the blue light-emitting layer 163B. More specifically, first, as illustrated in FIG. 5A, an entire surface of the hole transport layer 162 is coated with an ink including the above-described material of the red light-emitting layer 163R with use of, for example, a slit coating method to form a red material layer 163RA. As the ink, an ink prepared by dissolving the material of the red light-emitting layer 163R in a solvent is used. The surface of the hole transport layer 162 may be coated with the ink by, for example, a spin coating method, an ink-jet method, or the like.

Subsequently, as illustrated in FIG. 5B, the mask 31R is selectively formed in a red sub-pixel region (on the pixel electrode 14 of the red organic EL device 10R) on the red material layer 163RA. The mask 31R is so formed as to be in contact with the red material layer 163RA. Thereafter, a portion exposed from the mask 31R of the red material layer 163RA is removed by wet etching (refer to FIG. 5C). Thus, the red light-emitting layer 163R with the same planar shape as that of the mask 31R is formed. The mask 31R may be formed with use of, for example, a reverse offset printing method.

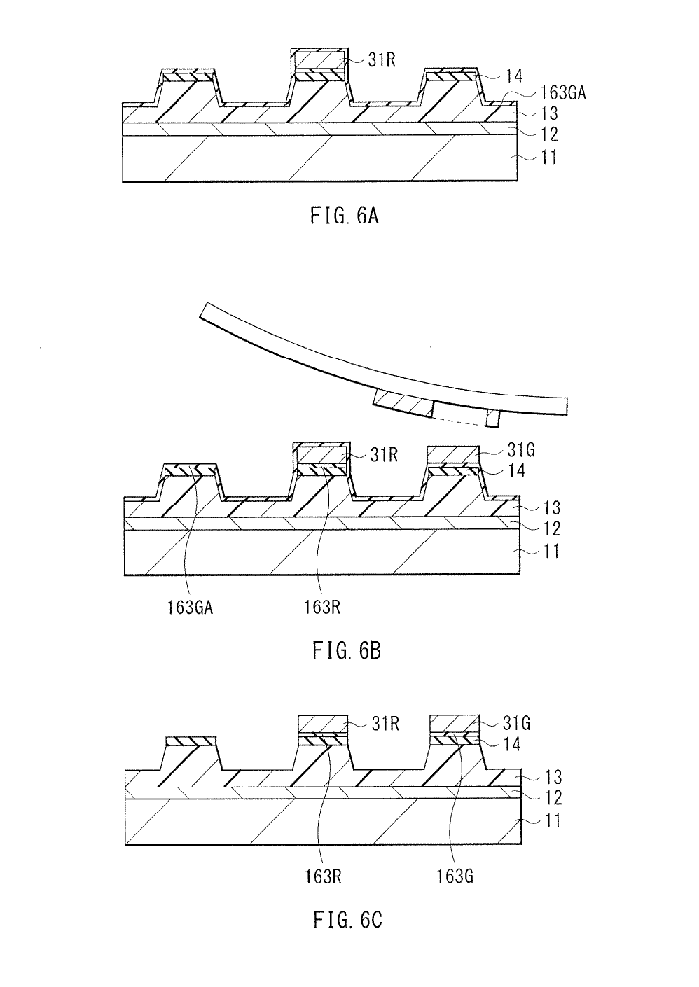

Subsequently, the green light-emitting layer 163G is formed. First, as illustrated in FIG. 6A, as with the above-described red material layer 163RA, a green material layer 163GA made of the material of the green light-emitting material 163G is formed on the hole transport layer 162 (not illustrated) on which the red light-emitting layer 163R is provided. At this time, the mask 31R may be covered with the green material layer 163GA. Subsequently, as illustrated in FIG. 6B, after the mask 31G is formed in a green sub-pixel region on the green material layer 163GA, a portion exposed from the mask 31G of the green material layer 163GA is removed (refer to FIG. 6C). The mask 31G is so formed as to be in contact with the green material layer 163GA. Thus, the green light-emitting layer 163G with the same planar shape as that of the mask 31G is formed. The mask 31G may be formed by, for example, a reverse offset printing method as with the mask 31R.

The blue light-emitting layer 163B is formed by, for example, the following manner. First, as illustrated in FIG. 7A, as with the above-described red material layer 163RA, a blue material layer 163BA made of the material of the blue light-emitting layer 163B is formed on the hole transport layer 162 (not illustrated) on which the red light-emitting layer 163R and the green light-emitting layer 163G are provided. At this time, the masks 31R and 31G may be covered with the blue material layer 164BA. Subsequently, as illustrated in FIG. 7B, after the mask 31B is formed in a blue sub-pixel region on the blue material layer 163BA, a portion exposed from the mask 31B of the blue material layer 163BA is removed (refer to FIG. 7C). The mask 31B is so formed as to be in contact with the blue material layer 163BA. Thus, the blue light-emitting layer 163B is formed. As with the above-described masks 31R and 31G, the mask 31G may be formed by, for example, a reverse offset printing method. The red light-emitting layer 163R, the green light-emitting layer 163G, and the blue light-emitting layer 163B may be formed in any order. For example, the green light-emitting layer 163G, the red light-emitting layer 163R, and the blue light-emitting layer 163B may be formed in this order.

After the light-emitting layer 163 (the red light-emitting layer 163R, the green light-emitting layer 163G, and the blue light-emitting layer 163B) is thus formed, the masks 31R, 31G, and 31B are dissolved in, for example, a solvent to be removed (refer to FIG. 7D). The solvent may be selected according to the material of the mask 31R, 31G, and 31B. As the solvent, a solvent allowing the masks 31R, 31G, and 31B to be dissolved therein and not allowing the light-emitting layer 163 to be dissolved therein may be preferably used. Examples of a combination of such a mask material and such a solvent may include a combination of a water-soluble resin and water, a combination of an alcohol-soluble resin and an alcohol-based solvent, and a combination of a fluorine-based resin and a fluorine-based solvent.

After the masks 31R, 31G, and 31B are removed, the electron transport layer 164, the electron injection layer 165, and the counter electrode 17 made of the above-described materials are formed in this order on the light-emitting layer 163 by, for example, an evaporation method. The electron transport layer 164, the electron injection layer 165, and the counter electrode 17 may be successively formed in a same film formation apparatus.

After the counter electrode 17 is formed, a protective layer is formed by, for example, an evaporation method or a CVD method. At this time, a film formation temperature may be preferably set to room temperature in order to suppress a decline in luminance associated with deterioration in the light-emitting layer 163 and the like, and film formation may be preferably performed under a condition that stress on a film is minimized in order to prevent peeling of the protective layer. The light-emitting layer 163, the electron transport layer 164, the electron injection layer 165, the counter electrode 17, and the protective layer may be preferably formed successively in a same film formation apparatus without being exposed to the air in order to suppress deterioration caused by atmospheric moisture.

After the protective layer is formed, the counter substrate 21 is bonded onto the protective layer with the sealing layer 18 in between. Thus, the display unit 1 is completed.

### (1-4. Functions and Effects)

In the display unit 1, the scanning signal is supplied from the scanning line drive circuit 130 to each of the sub-pixels 5R, 5G, and 5B through the gate electrode of the writing transistor Tr2, and the image signal supplied from the signal line drive circuit 120 is retained in the retention capacitor Cs through the writing transistor Tr2. In other words, on-off control of the driving transistor Tr1 is performed in response to the signal retained in the retention capacitor Cs, and a drive current Id is thereby injected into the red organic EL devices 10R, the green organic EL devices 10G, and the blue organic EL devices 10B to allow the red organic EL devices 10R, the green organic EL devices 10G, and the blue organic EL devices 10B to emit light by the recombination of holes and electrons.

At this time, the red organic EL devices 10R, the green organic EL devices 10G, and the blue organic EL devices 10B emit red light (with a wavelength from about 620 nm to about 750 nm both inclusive), green light (with a wavelength from about 495 nm to about 570 nm both inclusive), and blue light (with a wavelength from about 450 nm to about 495 nm both inclusive), respectively.

In recent years, an organic EL display unit having a larger screen and higher definition has been demanded. A printing method is used as a method of manufacturing the organic EL display unit, since process cost in the printing method is lower than in a vacuum deposition method, and upsizing is easy in the printing method. In particular, the reverse offset printing method is considered as a promising method used as a method of manufacturing the organic EL display unit, since a film with a uniform thickness is allowed to be formed, and high-definition patterning is allowed to be performed. However, for example, in a case where a light-emitting layer of an organic EL device is formed with use of the reverse offset printing method, an impurity such as siloxane included in a printing blanket material may be mixed into the light-emitting layer, thereby causing deterioration in characteristics such as light emission efficiency and light emission lifetime. Moreover, a light-emitting material ink having permeated into the blanket may be transferred to a pixel of a color different from that of the ink, thereby causing color mixture.

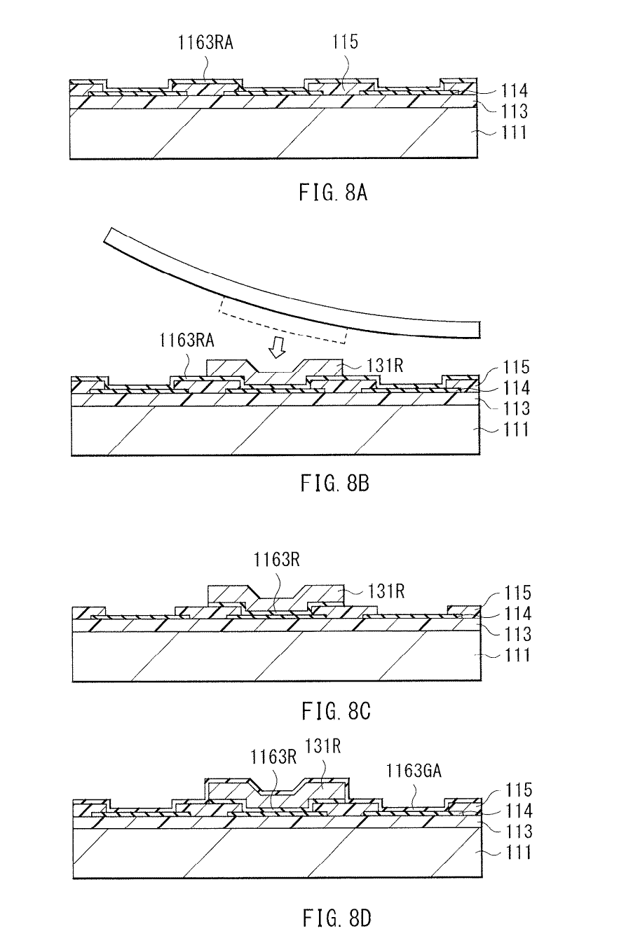

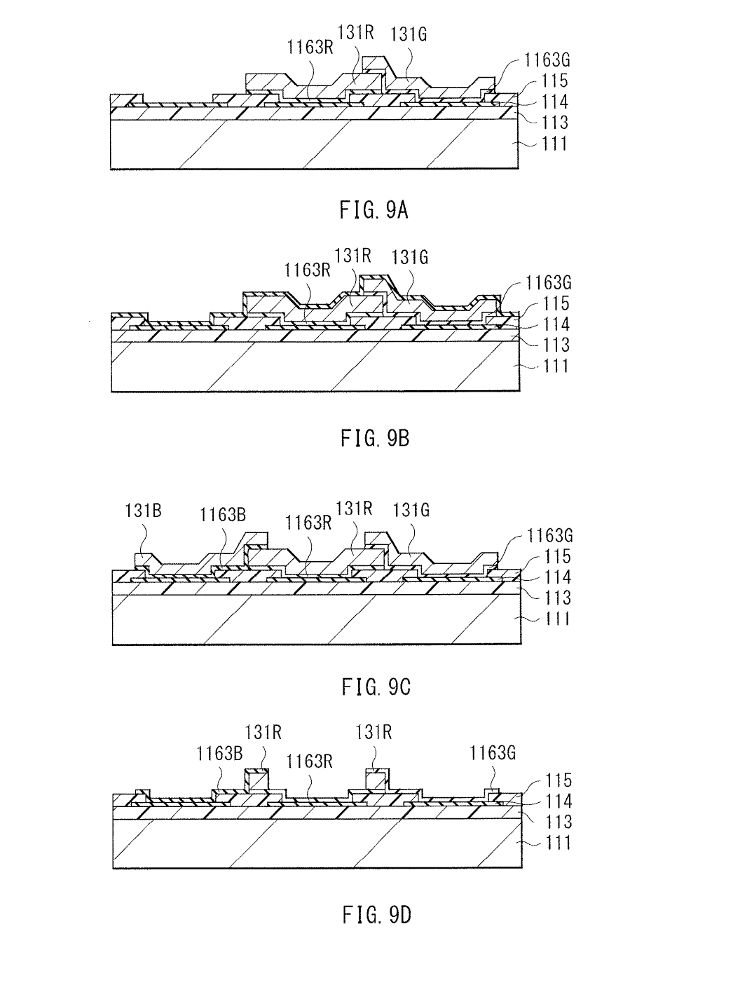

Therefore, for example, as illustrated in FIGS. 8A to 9D, as with the above-described method of forming the light-emitting layers 163R, 163G, and 163B, a method of performing patterning on light-emitting layers 1163R, 1163G, and 1163B of respective colors with use of masks 131R, 131G, and 131B may be considered. When such a method is adopted, the impurity transferred from the printing blanket to the light-emitting layers is removed during the patterning. Moreover, when a mask material having no compatibility with the light-emitting material is used, deterioration in light emission efficiency and reduction in light emission lifetime are preventable.

However, as illustrated in FIGS. 8A to 9D, in the display unit in which the sub-pixels 5R, 5G, and 5B are disposed on the flat planarization layer 113 and the partition wall protruded from the surface of the pixel electrode is provided between the sub-pixels, in a case where patterning is performed on the red light-emitting layer 1163R, the green light-emitting layer 1163G, and the blue light-emitting layer 1163 simply using the masks 131R, 131G, and 131B on the sub-pixels 5R, 5G, and 5B, as illustrated in FIG. 9D, the light-emitting layer may serve as a protective film, and accordingly, in a portion where the masks overlap each other between adjacent sub-pixels of different kinds, one of the masks may remain without being dissolved and removed. The water-soluble resin, the alcohol-soluble resin, the fluorine-based resin, or the like as the material of the remaining mask may outgas, thereby causing defective light emission.

Moreover, even if displacement of printing or variation in printing pattern size occurs, in order to avoid overlapping of the masks, it is necessary to have a sufficiently wide space between the sub-pixels. However, the wide space between the sub-pixels may be disadvantageous in terms of an increase in image resolution or an increase in area of a light emission pixel (a so-called aperture ratio).

On the other hand, in this embodiment, the concave section 131A is provided between adjacent sub-pixels of different kinds of the sub-pixels 5R, 5G, and 5B. Therefore, a narrow space between pixels in consideration of a printing position and variation in pattern size is allowed to be designed. Further, the masks 131R, 131G, and 131B are allowed to be prevented from remaining due to overlapping of the adjacent light-emitting layers of different colors of the light-emitting layers 1163R, 1163G, and 1163B when the light-emitting layers 1163R, 1163G, and 1163B are formed with use of the masks 131R, 131G, and 131B illustrated in FIGS. 8A to 9D.

As described above, in the display unit 1 according to this embodiment and the method of manufacturing the display unit 1, the concave section 131A is provided between the adjacent sub-pixels of different kinds of the sub-pixels 5R, 5G, and 5B, and the light-emitting layer 163R, 163G, and 163B are formed with use of the masks 31R, 31G, and 31B. Therefore, overlapping of the masks due to displacement of printing that may be caused when using a method of suppressing mixture of an impurity into the light-emitting layer by providing masks (the masks 131R, 131G, and 131B) on predetermined light-emitting layers, for example, as illustrated in FIGS. 8A to 9D, is preventable. Therefore, a distance (pitch) between pixels in consideration of the occurrence of displacement is allowed to be decreased. In other words, image resolution is allowed to be improved, and a display unit with high definition and high reliability and an electronic apparatus including the display unit are achievable.

Modification examples of this embodiment will be described blow. In the following description, like components are denoted by like numerals as of the above-described embodiment, and will not be further described.

### 2. Modification Example

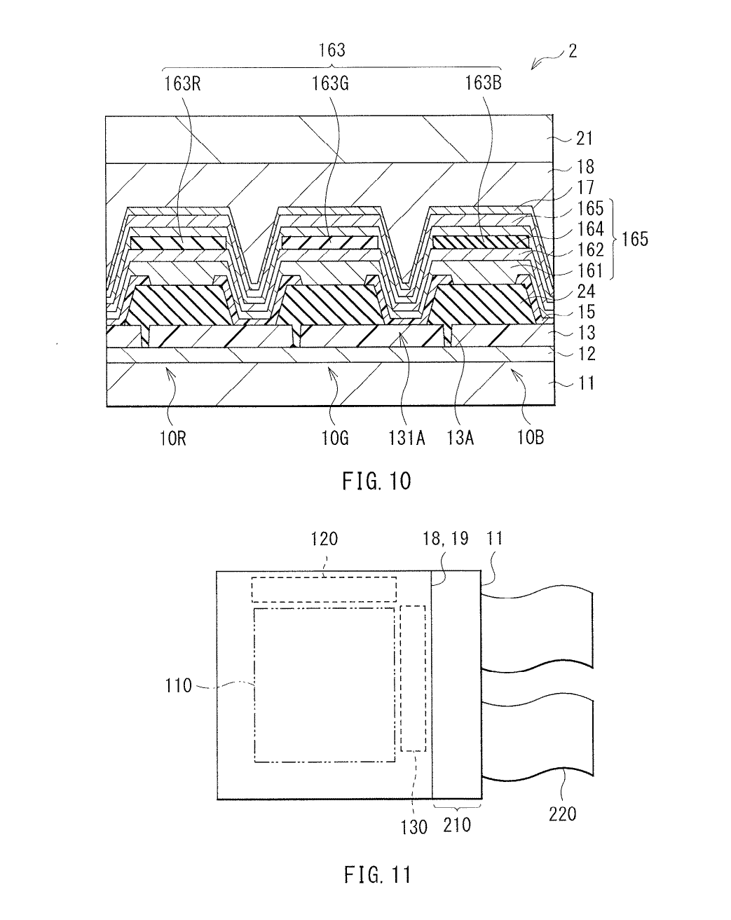

FIG. 10 illustrates a sectional configuration of a display unit (a display unit 2) according to Modification Example 1 of the above-described embodiment. The display unit 2 may be used as, for example, a mobile terminal unit such as a tablet or a smartphone. The display unit 2 may be an organic EL display unit, and may include, for example, the red organic EL devices 10R, the green organic EL devices 10G, and the blue organic EL devices 10B as light-emitting devices on the drive substrate 11 with the TFT (Thin Film Transistor) layer 12 and the planarization layer 13 in between. This modification example differs from the above-described embodiment in that a concave section 131A between sub-pixels of different colors is provided by a thickness of a pixel electrode 24.

As illustrated in FIG. 10, the concave sections 231A may be formed by the thickness of the pixel electrode 24 on the planarization film 13 with a flat surface. The thickness of the pixel electrode 24 may be large enough not to transfer the masks 31R, 31G, and 31B to a region (for example, a region between pixels) other than predetermined regions when the light-emitting layers 163R, 163G, and 163B are formed with use of the above-described method illustrated in FIGS. 5A to 7D. More specifically, the thickness may be preferably, for example, from about 0.5 μm to about 2 μm both inclusive in consideration of distortion of the drive substrate 11 caused by remaining stress upon formation of an electrode film (the pixel electrode 24), material cost, and the like. In order to achieve easy processing and prevent transfer of the masks, as with the above-described embodiment, a ratio between a distance (A) between pixels and a depth (B) of the concave section 131A may be preferably, for example, from about 1:1 to about 100:1 both inclusive.

### 3. Application Examples

Application Examples of the display units 1 and 2 described in the above-described embodiment and the above-described modification example will be described below. The display units according to the above-described embodiment and the like are applicable to display units of electronic apparatuses, in any fields, that display an image signal inputted from outside or an image signal produced inside as an image or a picture, such as televisions, digital cameras, notebook personal computers, mobile terminal units such as mobile phones, and video cameras.

### (Module)

The display unit 1 including the organic EL devices 10R, 10G, and 10B according to the above-described embodiment may be incorporated as, for example, a module illustrated in FIG. 11 into various electronic apparatuses such as Application Examples 1 and 2 that will be described later. This module may be configured, for example, by providing a region 210 exposed from the protective film 16 and the counter substrate 21 on one side of the drive substrate 11 and extending wiring lines of the signal line drive circuit 120 and the scanning line drive circuit 130 to form an external connection terminal (not illustrated) in the exposed region 210. A flexible printed circuit (FPC) 220 for signal input and output may be provided to the external connection terminal.

### Application Example 1

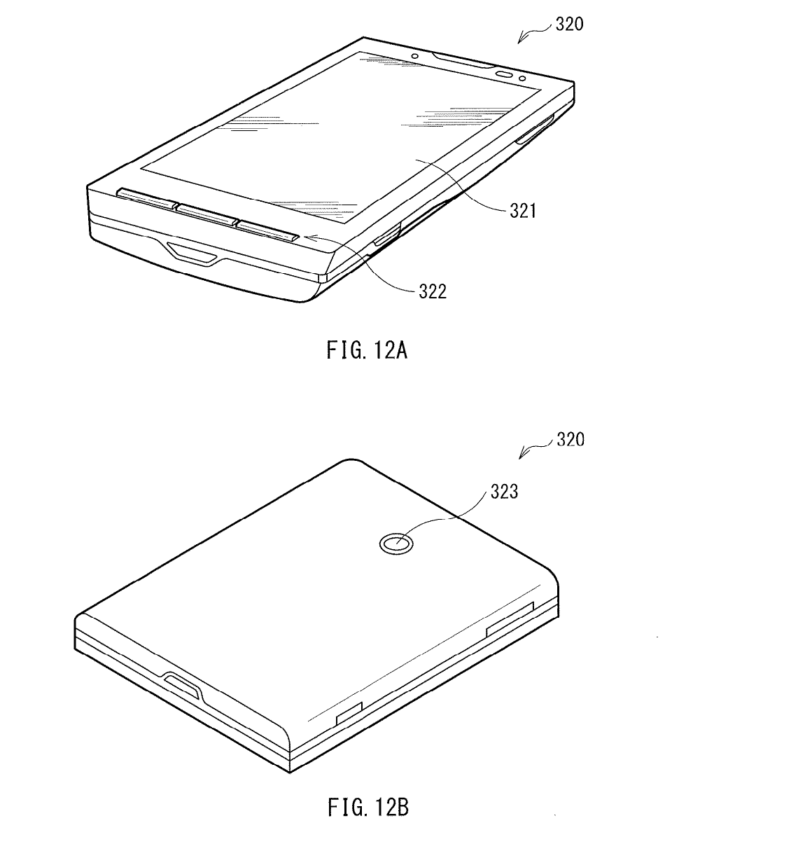

FIGS. 12A and 12B illustrate an appearance of a smartphone 320 according to Application Example 1. The smartphone 320 may include, for example, a display section 321, an operation section 322 on a front side, and a camera 323 on a back side. The display unit 1 according to the above-described embodiment is mounted in the display section 321.

### Application Example 2

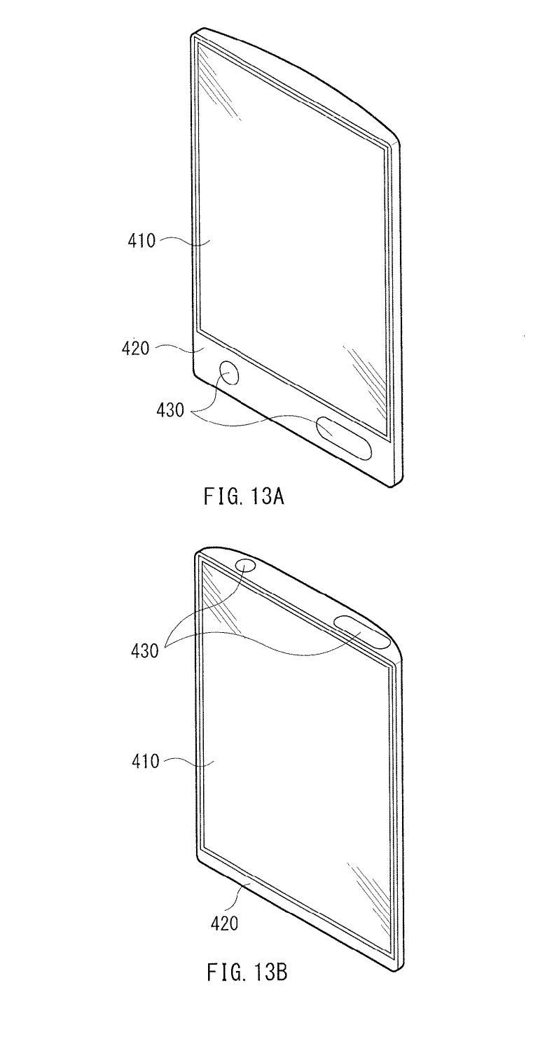

FIGS. 13A and 13B illustrate an appearance of a tablet personal computer according to Application Example 2. The tablet personal computer may include, for example, a housing (a non-display section) 420 in which a display section 410 and an operation section 430 are disposed. The display unit 1 according to the above-described embodiment is mounted in the display section 410.

### (Illumination Unit)

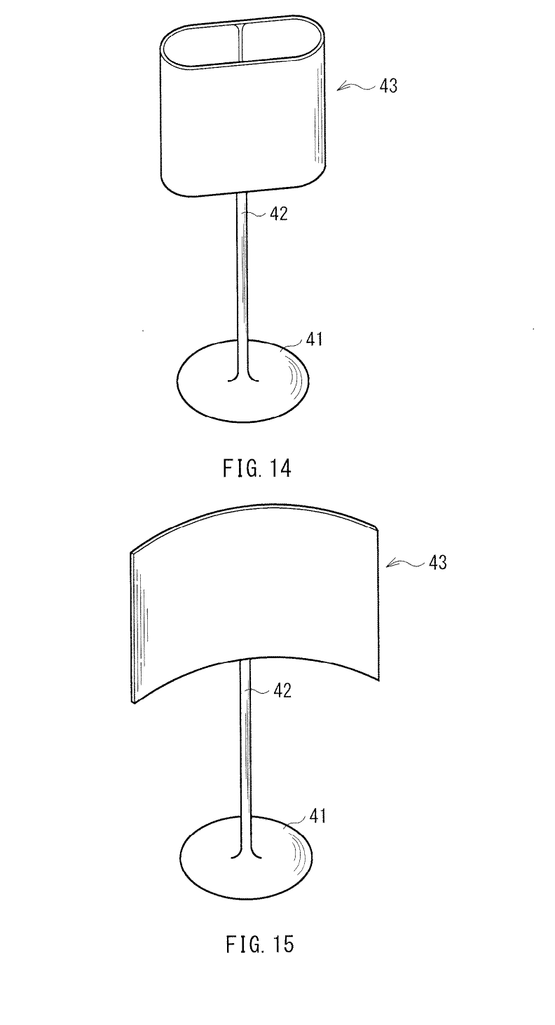

An illumination unit may be configured of the red organic EL devices 10R, the green organic EL devices 10G, and the blue organic EL devices 10B described in the above-described embodiment and the above-described modification example. FIGS. 14 and 15 illustrate appearances of a desk illumination unit configured by arranging a plurality of red organic EL devices 10R, a plurality of green organic EL devices 10G, and a plurality of organic EL devices 10B. The illumination unit may include, for example, an illumination section 43 attached to a rod 42 provided on a base 41, and the illumination section 43 is configured of the red organic EL devices 10R, the green organic EL devices 10G, and the blue organic EL devices 10B in one of the above-described embodiment and the like. When the illumination section 43 uses a flexible substrate such as a resin substrate as the drive substrate 11, the illumination section 43 may have an arbitrary shape such as a tubular shape illustrated in FIG. 14 or a curved shape illustrated in FIG. 15.

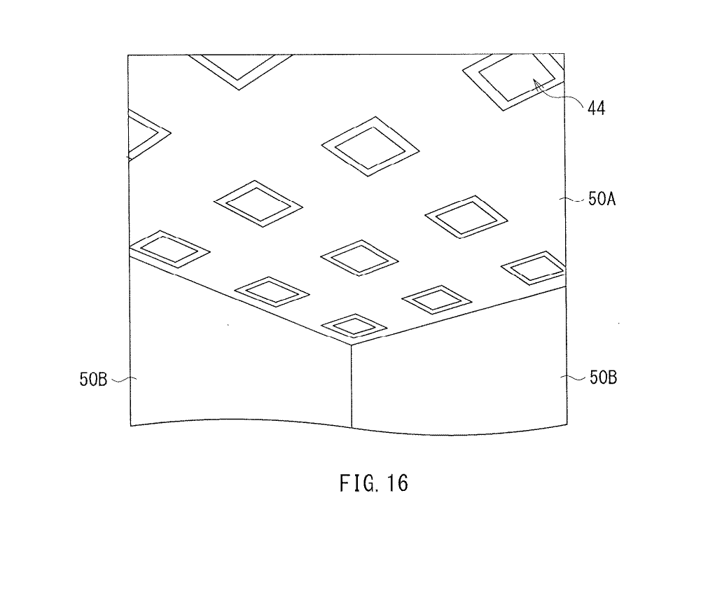

FIG. 16 illustrates an appearance of a room illumination unit using the red organic EL devices 10R, the green organic EL devices 10G, and the blue organic EL devices 10B in one of the above-described embodiments and the like. The illumination unit may include, for example, an illumination section 44 configured of the red organic EL devices 10R, the green organic EL devices 10G, and the blue organic EL devices 10B in one of the above-described embodiments and the like. The desired number of the illumination sections 44 are arranged at desired intervals on a ceiling 50A of a building. It is to be noted that the illumination sections 44 may be disposed on an arbitrary place such as a wall 50B or a floor (not illustrated) in addition to the ceiling 50A, depending on the intended use.

Although the present technology is described referring to the embodiments and the modification examples, the present technology is not limited thereto, and may be variously modified. For example, in the above-described embodiment and the like, a case where patterning is performed on the light-emitting layer 163 is described; however, patterning may be performed on any other layer of the organic layer 16 with use of a mask. Patterning may be collectively performed on a plurality of layers, for example, the hole injection layer 161, the hole transport layer 162, the light-emitting layer 163, the electron transport layer 164, and the electron injection layer 165 in each of the red organic EL device 10R, the green organic EL device 10G, and the blue organic EL device 10B.

Moreover, in the above-described embodiment and the like, a case where the organic layer 16 includes the hole injection layer 161, the hole transport layer 162, the light-emitting layer 163, the electron transport layer 164, and the electron injection layer 165 is described; however, layers other than the light-emitting layer 163 may be omitted if necessary.

Further, for example, in the above-described embodiment and the like, the active matrix display unit is described; however, a passive matrix display unit may be adopted.

Furthermore, for example, in the above-described embodiment and the like, a case where the pixel electrode 14 and the counter electrode 17 serve as an anode and a cathode, respectively, is described; however, the pixel electrode 14 and the counter electrode 17 may serve as a cathode and an anode, respectively.

In addition thereto, the material and thickness of each layer, the method and conditions of forming each layer are not limited to those described in the above-described embodiment and the like, and each layer may be made of any other material with any other thickness by any other method under any other conditions.

It is to be noted that the effects described in this description are merely examples; therefore, effects in the present technology are not limited thereto, and the present technology may have other effects.

It is to be noted that the present technology may have the following configurations.

(1) A display unit including:

a substrate;

a plurality of pixels provided on the substrate, each of the pixels including a light-emitting device, the light-emitting devices being configured to emit colors different from each other; and

a concave section provided between the pixels.

(2) The display unit according to (1), in which

each of the light-emitting devices includes a first electrode, an organic layer including at least a light-emitting layer, and a second electrode in this order from the substrate,

a pixel separation film is included between the pixels, the pixel separation film covering an outer edge of the first electrode and being formed with a uniform thickness, and

a depth of the concave section is larger than the thickness of the pixel separation film covering the outer edge of the first electrode.

(3) The display unit according to (2), in which the depth of the concave section is from about 0.5 μm to about 2 μm both inclusive.

(4) The display unit according to (2) or (3), in which a ratio between a distance (A) between the pixels and a distance (B) from a surface of the first electrode to a bottom surface of the concave section is from about 1:1 to about 100:1 both inclusive.

(5) The display unit according to any one of (2) to (4), in which

each of the plurality of pixels includes a thin film transistor and the light-emitting device from the substrate, and includes a common planarization layer between the thin film transistor and the light-emitting device, the planarization layer being shared by the plurality of pixels, and

the concave section is formed by a recessed-protruding portion of the planarization layer.

(6) The display unit according to any one of (2) to (5), in which

each of the plurality of pixels includes a thin film transistor and the light-emitting device from the substrate, and includes a common planarization layer between the thin film transistor and the light-emitting device, the planarization layer being shared by the plurality of pixels, and

the concave section is formed by a level difference between the planarization layer and the first electrode.

(7) A method of manufacturing a display unit including:

forming a concave section between pixels provided on a substrate, each of the pixels including a light-emitting device, the light-emitting devices configured to emit colors different from each other; and

forming the light-emitting devices in the pixels.

(8) The method of manufacturing the display unit according to (7), in which

an organic material layer forming the light-emitting devices is formed on the substrate, and

after a mask is formed in a region corresponding to a predetermined pixel on the organic material layer, the organic material layer is selectively removed to form an organic layer in the predetermined pixel.

(9) An electronic apparatus provided with a display unit, the display unit comprising:

a substrate;

a plurality of pixels provided on the substrate, each of the pixels including a light-emitting device, the light-emitting devices being configured to emit colors different from each other; and

a concave section provided between the pixels.

It should be understood by those skilled in the art that various modifications, combinations, sub-combinations, and alterations may occur depending on design requirements and other factors insofar as they are within the scope of the appended claims or the equivalents thereof.

What is claimed is:

1. A display unit comprising:
a substrate;
a plurality of pixels provided on the substrate, each of the pixels including a light-emitting device, the light-emitting devices being configured to emit colors different from each other; and
a concave section provided between the pixels.

2. The display unit according to claim 1, wherein
each of the light-emitting devices includes a first electrode, an organic layer including at least a light-emitting layer, and a second electrode in this order from the substrate,
a pixel separation film is included between the pixels, the pixel separation film covering an outer edge of the first electrode and being formed with a uniform thickness, and
a depth of the concave section is larger than the thickness of the pixel separation film covering the outer edge of the first electrode.

3. The display unit according to claim 2, wherein the depth of the concave section is from about 0.5 μm to about 2 μm both inclusive.

4. The display unit according to claim 2, wherein a ratio between a distance (A) between the pixels and a distance (B) from a surface of the first electrode to a bottom surface of the concave section is from about 1:1 to about 100:1 both inclusive.

5. The display unit according to claim 2, wherein
each of the plurality of pixels includes a thin film transistor and the light-emitting device from the substrate, and includes a common planarization layer between the thin film transistor and the light-emitting device, the planarization layer being shared by the plurality of pixels, and
the concave section is formed by a recessed-protruding portion of the planarization layer.

6. The display unit according to claim 2, wherein
each of the plurality of pixels includes a thin film transistor and the light-emitting device from the substrate, and includes a common planarization layer between the thin film transistor and the light-emitting device, the planarization layer being shared by the plurality of pixels, and
the concave section is formed by a level difference between the planarization layer and the first electrode.

7. A method of manufacturing a display unit comprising:
forming a concave section between pixels provided on a substrate, each of the pixels including a light-emitting device, the light-emitting devices configured to emit colors different from each other; and
forming the light-emitting devices in the pixels.

8. The method of manufacturing the display unit according to claim 7, wherein
an organic material layer forming the light-emitting devices is formed on the substrate, and
after a mask is formed in a region corresponding to a predetermined pixel on the organic material layer, the organic material layer is selectively removed to form an organic layer in the predetermined pixel.

9. An electronic apparatus provided with a display unit, the display unit comprising:
a substrate;
a plurality of pixels provided on the substrate, each of the pixels including a light-emitting device, the light-emitting devices being configured to emit colors different from one another; and
a concave section provided between adjacent pixels of the pixels, the adjacent pixels including the light-emitting devices of colors at least different from each other.
